(19) United States
(12) Patent Application Publication
(10) Pub. No.: US 2012/0007605 A1
(43) Pub. Date: Jan. 12, 2012

(54) HIGH FREQUENCY MEASUREMENT SYSTEM

(76) Inventor: Johannes Benedikt, Cardiff (GB)

(21) Appl. No.: 13/133,340

(22) PCT Filed: Dec. 8, 2009
(86) PCT No.: PCT/GB2009/002847

§ 371 Date: Sep. 12, 2011

(30) Foreign Application Priority Data
Dec. 8, 2008 (GB) 0822367.9

(51) Int. Cl. G01R 27/28; G01R 31/28; G01R 23/20

(52) U.S. Cl. 324/612; 324/128; 29/593

(57) ABSTRACT

The invention concerns a high frequency non-linear measurement system for analysing the behaviour of a high frequency device, for example a device for use in a high power, high frequency amplifier, such as an amplifier for use in a mobile telephone network or other telecommunications-related base-station. An embodiment of the invention provides a high frequency non-linear measurement system including one or more multiplexer circuits. Each multiplexer circuit comprises a first signal-combining circuit and a second signal-combining circuit. Each signal-combining circuit comprises a pair of directional couplers connected via a pair of signal filters arranged in parallel.

### BACKGROUND OF THE INVENTION

The present invention concerns a high frequency non-linear measurement system. More particularly, but not exclusively, this invention concerns a measurement system for analysing the behaviour of a high frequency device, for example, a device for use in a high power (large signal) high frequency amplifier, such as an amplifier for use in a mobile telephone network or other telecommunications-related base-station. The invention also concerns a method of measuring the response of an electronic device to a high frequency input signal, a method of improving the design of a high frequency high power device or a circuit including such a device, and/or manufacturing such an improved device.

It is desirous to improve the efficiency and power capabilities of high-power high-frequency devices, such as amplifiers for use in mobile communication base stations. The behaviour of such devices, being non-linear over much of their operating range, is rather complicated and difficult to model accurately and, as such, measurement systems are typically used to measure the characteristics of, and improve the design of, such devices.

When analysing the behaviour of a high frequency electronic device it is often desired to assess the behaviour of the device under the sort of conditions that the device might be subjected to during normal operation. For example, the impedance to which the device is attached during its normal/final operation may determine to a high degree the performance, for example the efficiency and/or linearity, of the device. Such considerations are for example of particular relevance when designing high frequency large signal amplifier circuits for use in for example a mobile telecommunications base station. It is therefore desirous to be able to analyse the device when subjected to a virtual load/virtual impedance at the input and/or output of the device. One means of applying such a virtual impedance is to apply an active load pull, wherein a signal with a given magnitude and phase relative to an input signal inputted into the device under test is injected into a port (for example the input or output) of the device under test.

If one is to assess the performance of a non-linear device or of a device that exhibits non-linear behaviour it may be desirable to apply loads at a port of the device under test (DUT) having (variable) components at not only the fundamental frequency but also the first, and perhaps second and higher, harmonic frequencies. To apply such loads simultaneously at a port of the DUT as a composite signal, it would be convenient to provide one or more multiplexer circuits to combine the components into the single composite signal. It would also be convenient to provide one or more demultiplexer circuits to allow manipulation of the individual frequency components of the composite load pull signal.

The use of traditional multiplexer devices and demultiplexer devices in a method of measuring the high-frequency behaviour of a DUT is unsatisfactory because such devices have poor transmission and reflection characteristics at certain frequencies. For example, multiplexers tend to reflect signals at frequencies higher than the operational frequency range (i.e. outside the multiplexer's pass-band). Such characteristics can lead to instabilities, such as oscillations, in the measurement system caused by unchecked positive feedback of signals at certain frequencies. Also, power consumption and requirements are higher than desirable.

The present invention seeks to mitigate the above-mentioned problems. Alternatively or additionally, the present invention seeks to provide an improved measurement system.

### SUMMARY OF THE INVENTION

The present invention provides, according to a first aspect of the invention, a high frequency non-linear measurement system including one or more multiplexer circuits, wherein each multiplexer circuit comprises a first signal-combining circuit and a second signal-combining circuit, each signal-combining circuit comprising a pair of directional couplers connected via a pair of signal filters arranged in parallel.

As a result of the multiplexer circuit being formed by pairs of directional couplers and signal filtering circuits it is possible for the multiplexer to exhibit low reflectivity at both pass-band frequencies and at frequencies outside, and in particular above, the pass-band of the multiplexer.

The multiplexer is advantageously constructed such that it may be used in a reverse configuration, with very little modification, as a demultiplexer.

The present invention thus provides, according to a second aspect of the invention, high frequency non-linear measurement system including one or more demultiplexer circuits, wherein each demultiplexer circuit comprises a first signal-splitting circuit and a second signal-splitting circuit, each signal-splitting circuit comprising a pair of directional couplers connected via a pair of signal filters arranged in parallel.

The non-linear measurement system is non-linear in the sense that it is able to measure and analyse the non-linear behaviour of a device under test, for example at frequencies and powers at the upper end of the operating range of the device. The measurement system is a high frequency measurement system in the sense that it is able to measure frequencies as high as 1 GHz, and more preferably as high as 10 GHz. The measurement system may be arranged to be able to measure signals at frequencies as high as 100 GHz.

A multiplexer is typically considered as a device that combines different signals into a composite signal, whereas a demultiplexer is typically considered as a device that splits a signal into different components. In the context of the present invention, the term multiplexer may encompass a device that is able to act as a demultiplexer, and vice versa. Similarly, a signal splitting circuit of the invention may act as a signal combining circuit and vice versa. How such circuits and device operate will depend on their use in situ in the measurement system. The following description relates to features of the invention that are largely independent of whether the direction in which the multiplexer/demultiplexer and signal splitting/signal combining circuits are used.

The signal filters of each pair of signal filters preferably have substantially the same frequency characteristics. For example, each signal filter preferably causes the same phase change on signals of identical frequency. If one signal filter causes a different phase change from the phase change caused by the other signal filter of the pair, then it may be desirable to correct the phase change so that between the two directional couplers, the phase changes are matched. In the illustrated embodiments of the invention, the signal filters of the first signal-splitting/signal-combining circuit have different frequency characteristics from the signal filters of the second signal-splitting/signal-combining circuits. For example, the frequency pass-band of the filters may be set at a higher frequency in the filters of one signal-splitting/signal-combining circuit than in the filters of the other signal-splitting/signal-combining circuit.

At least one of the signal filters may be a low pass filter. At least one of the signal filters may be a band-pass filter. At least one of the signal filters may be a high pass filter. A combination of low pass, band pass, and high pass filters may be used.

The directional couplers are preferably in the form of hybrid couplers, more preferably 3 dB quadrature (90-degree) hybrid couplers.

The multiplexer preferably comprises a plurality of signal-combining circuits arranged in a cascade, an output of the signal-combining circuit in the cascade providing an input to a subsequent signal-combining circuit in the cascade. A demultiplexer of the invention may similarly comprise a plurality of signal-splitting circuits arranged in a cascade.

The one or more multiplexer/demultiplexer circuits preferably form part of a load pull system for emulating an impedance at one of the ports of a device-under-test to be analysed by the measurement system. Thus, the measurement system may apply multiple load pulls on the device under test.

The measurement system may include a waveform generator. The waveform generator may be arranged to generate both a giga-Hertz frequency waveform (i.e. a signal having a fundamental frequency of between 1 GHz and 999 GHz) at the same time as a mega-Hertz frequency waveform (i.e. a signal having a fundamental frequency of between 1 MHz and 999 MHz). The measurement system may also include a DC source. Thus, the measurement system may be configured to apply a signal at a device under test that comprises a DC component, a low-frequency modulation signal component and a high-frequency signal component. In the present context, low-frequency signals are signals that have frequencies low relative to the high-frequency signals in the measurement system. As such, signals having a frequency of the order of several MHz may still be considered as a low-frequency. In the present context, a low-frequency may thus optionally be defined as a signal having a fundamental frequency of less than 500 MHz.

The measurement system may be arranged to measure signals having a low-frequency modulation signal component and to extract information contained in those signals. The measurement system may alternatively, or additionally, be arranged to measure signals having a high-frequency signal component, and to extract information contained in such signals.

It will of course be appreciated that the first and second aspect of the present invention are closely related. Both aspects may be embodied by a single embodiment of the invention. Thus, the measurement system may include one or more multiplexer circuits according to the first aspect of the invention and one or more demultiplexer circuits according to the second aspect of the invention.

A measurement system in accordance with the first and/or the second aspects of the invention may be used in a method of measuring the response of an electronic device to a high frequency input signal.

According to a third aspect of the invention, there is provided a method of measuring the response of an electronic device to a high frequency input signal, the method including the steps of:

providing an electronic device under test, the device having at least two ports,

providing a plurality of high-frequency signals at different frequencies,

modifying the plurality of high-frequency signals,

multiplexing the modified plurality of high-frequency signals into a combined load-pull signal,

applying a high-frequency test signal comprising the load-pull signal at a port of the device under test, and

measuring the response of the device-under-test to the test signal applied to the device,

wherein the multiplexing step is conducted by passing signals via a multiplexer circuit comprising a first signal-combining circuit and a second signal-combining circuit, each signal-combining circuit comprising a pair of directional couplers connected via a pair of signal filters arranged in parallel. The step of providing a plurality of high-frequency signals at different frequencies may be performed by providing multiple signal sources or may be performed by demultiplexing a signal produced by a single source.

According to a fourth aspect of the invention there is also provided a method of measuring the response of an electronic device to a high frequency input signal, the method including the steps of:

providing an electronic device under test, the device having at least two ports,

applying a high-frequency test signal, comprising a plurality of different high-frequency load-pull components, at a port of the device under test,

measuring the response of the device-under-test to the test signal applied to the device,

and

demultiplexing a high-frequency composite signal into a plurality of component parts,

wherein the demultiplexing step is conducted by passing signals via a multiplexer circuit comprising a first signal-splitting circuit and a second signal-splitting circuit, each signal-splitting circuit comprising a pair of directional couplers connected via a pair of signal filters arranged in parallel. The demultiplexing step may be performed to convert a composite signal into a plurality of different high-frequency load-pull components to be manipulated (for example amplified by different amounts) and then recombined to form at least part of the high-frequency test signal applied to the DUT. Alternatively, or additionally, the demultiplexing step may be performed to convert a measured composite signal (relating to, for example, a measurement taken at a part of the measurement system circuit, for example at a port of the DUT) into a plurality of different high-frequency components for subsequent analysis.

The third and fourth aspects of the invention may be combined in a fifth aspect of the invention, which relates to a method of measuring the response of an electronic device to a high frequency input signal. For example a method according to the fifth aspect of the invention may include the steps of:

providing an electronic device under test, the device having at least two ports,

demultiplexing a high-frequency composite signal into a plurality of component parts,

modifying the plurality of component parts,

multiplexing the modified plurality of component parts into a combined load-pull signal,

applying a high-frequency test signal comprising the load-pull signal at a port of the device under test, and

measuring the response of the device-under-test to the test signal applied to the device, wherein the multiplexing and demultiplexing step is conducted by passing signals via a respective multiplexer circuit, each multiplexer circuit comprising a first signal-combining/signal-splitting circuit and a second signal-combining/signal-splitting circuit, each signal-combining/signal-splitting circuit comprising a pair of directional couplers connected via a pair of signal filters arranged in parallel.

The third, fourth and fifth aspects of the invention, are closely related to each other, because they all relate to a method of measuring the response of an electronic device to a high frequency input signal utilising using a plurality of signal-changing circuits, each signal-changing circuit having a pair of directional couplers connected via a pair of signal filters arranged in parallel.

In the embodiment described below, the method includes a step of applying a waveform to the device, the waveform having a fundamental frequency at a first frequency and having a harmonic component at a second frequency substantially equal to an integer multiple of the first frequency.

The method of the invention may be repeated and performed in respect of a multiplicity of different input signals applied to the device.

The present invention also provides according to a sixth aspect of the invention a method of improving the design of a high frequency high power device or a circuit including a high frequency high power device including utilising at least one of the first to fifth aspects of the invention. The performance of the circuit may be improved by improving one or more of the efficiency, gain, or maximum power output of the circuit. The circuit may be improved in design by varying the bias point or drive level of the device, or by varying the harmonic tuning of the circuit. A circuit including the device may be tuned in response to the results of the testing so performed.

The method of improving the device/circuit may include outputting data relating to current and voltage waveforms outputted by the device, varying harmonic loads on the device, and then analysing the outputted data relating to current and voltage waveforms to assess the loads that facilitate the better performance of the device. A step may be performed by modifying the design of the device, or by modifying the circuit including the device, in consideration of the results of the analysing of the behaviour of the device.

An improved high power high frequency electronic circuit including the device may then be designed and manufactured.

The circuit may be a signal amplifier. The device may be a transistor. The device may be a non-linear electronic device.

According to a seventh aspect there is also provided a method of manufacturing a high frequency high power device or a circuit including a high frequency high power device, the method including the steps of improving the design of a similar existing device or of an existing circuit including such a device by performing the method of the sixth aspect of the invention and then manufacturing the device or the circuit including the device in accordance with the improved design.

According to an eighth aspect of the invention there is provided a high frequency non-linear measurement system including one or more multiplexer/demultiplexer circuits, wherein the multiplexer/demultiplexer circuits are each formed from a cascade of high frequency directional filters, preferably, but not necessarily, comprising one or more pairs of directional couplers connected via one or more signal filters. The directional filters may have a different basic structure, for example, utilising two or more waveguides and one or more coupling devices to couple between the two or more waveguides. Such a high frequency non-linear measurement system may include only multiplexer circuits of the type referred to above. Alternatively, the high frequency non-linear measurement system may include only demultiplexer circuits of the type referred to above.

It will of course be appreciated that features described in relation to one aspect of the present invention may be incorporated into other aspects of the present invention. For example, the method of the invention relating to improving the design of a device may incorporate use of the measurement system according to the first or second aspects of the invention and may incorporate any of the features of the measurement system described with reference to those aspects of the invention.

### DESCRIPTION OF THE DRAWINGS

Embodiments of the present invention will now be described by way of example only with reference to the accompanying schematic drawings of which:

FIG. 1 is a schematic circuit diagram illustrating a non-linear measurement system including an active load pull system and four multiplexer circuits according to a first embodiment;

FIG. 2 is a schematic circuit diagram of one of the multiplexer circuits ,shown in FIG. 1, the multiplexer circuit comprising a plurality of signals spitting circuits;

FIGS. 3a to 3c illustrates schematically the working of one of the signal spitting circuits of the multiplexer circuit of FIG. 2;

FIG. 4 is a schematic circuit diagram illustrating the operation of the multiplexer circuit shown in FIG. 2;

FIG. 5 is schematic circuit diagram illustrating the operation of a multiplexer circuit of a second embodiment of the invention;

FIG. 6 is schematic circuit diagram illustrating the operation of a multiplexer circuit of a third embodiment of the invention; and

FIG. 7 is a schematic circuit diagram showing a non-linear measurement system with active load pull circuits and multiplexers according to a fourth embodiment of the present invention.

### DETAILED DESCRIPTION

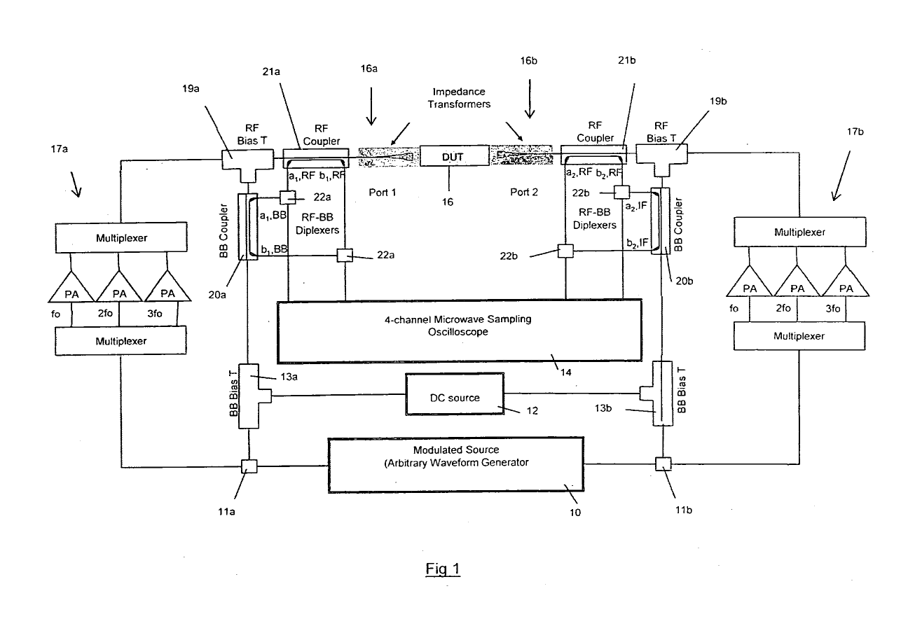

FIG. 1 is a schematic circuit diagram showing a high frequency non-linear measurement system according to a first embodiment of the present invention. The measurement system is based around a VNA (vector network analyser with integrated source). The VNA thus comprises a modulated source (arbitrary waveform generator) 10, DC source 12 and a microwave sampling oscilloscope 14. It will be appreciated that those three components can be provided in one product by means of commercially available vector network analysers.

The measurement system is arranged to measure characteristics bf a two-port device under test (DUT) 16. The modulated source generates not only the base-band modulation signal, having a frequency in the MHz range, but also the RF signals in the GHz range. The base-band signal is divided out from the signals outputted by the modulated source 10, by means of two diplexers 11, one 11a arranged to feed the input side of circuit and one 11b arranged to feed the output side of circuit. This base-band signal is combined with a DC current on each side by means of a respective base band bias T device 13a, 13b.

Non-linear measurement systems require the emulation of impedances at the input and output of a DUT. The impedance emulation has to be effected at all operational frequencies that are contained within the signal being input into the device and also output by the device. The impedance emulation is achieved through dedicated ‘load pull systems’.

The DUT 16 is connected to an active load pull circuit 17a, 17b at each port 16a, 16b. The load pull circuits each emulate (load) impedance at three different frequencies simultaneously. Each active load pull circuit 17 may thus be considered as comprising multiple load pull systems connected in parallel, each load pull system acting at a single (narrow band) frequency. Each load pull circuit 17 is arranged to apply a signal at a port 16a, 16b of the DUT, the signal comprising a DC component and a high-frequency multi-component signal. The high-frequency multi-component signal has three different high-frequency components at a fundamental frequency f₀ and two harmonic frequencies 2f₀ and 3f₀. A bias T device combines the DC component provided by the DC source of the VNA and the high-frequency multi-component signal. The high-frequency multi-component signal is produced by means of demultiplexing, with a first multiplexer. circuit, a waveform produced by the high-frequency source of the VNA into three component frequencies, centred on the fundamental frequency f₀ and the first two harmonic frequencies 2f₀ and 3f₀, amplifying the three components by desired, optionally different, amounts by three parallel arranged amplifiers, and then recombining the three signals with a second multiplexer circuit.

On the input side of the circuit, the signal outputted by the load pull circuit 17a is combined with the modulation signal from the base band bias T device 13a, by means of an RF bias T device 19a, and fed to the input port (“Port 1”) 16a of the DUT 16. The output side similarly has an RF bias T device 19b supplying the output port (“Port 2”) 16b of the DUT 16. The oscilloscope 14 measures waveforms in the circuit both at base band frequencies and at RF frequencies by means of base-band couplers 20a, 20b and RF couplers 21a, 21b, connected to the oscilloscope 14 via RF-base-band diplexers 22a, 22b. The DUT 16 is connected to the system via impedance transformers 23a, 23b which transform the impedance of the DUT seen by the measurement system to reduce power usage, by reducing impedance mismatch.

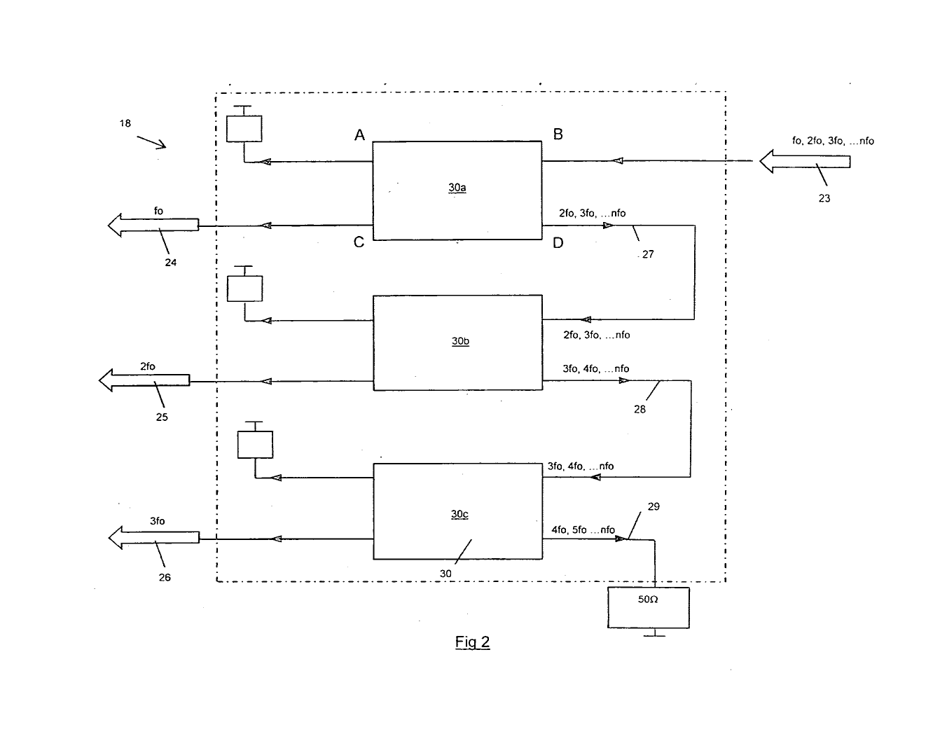

It is important that the electronic components used in the measurement system have characteristics that do not lead the measurement system to generate unintentional load pull oscillations (typically generated by positive feedback loops in the system). The multiplexer circuits 18 used in the system need not only to have good characteristics at frequencies within the pass-bands of the multiplexers, but also to be well behaved at frequencies outside the pass-bands. The multiplexer circuits used in the measurement system of FIG. 1 will now be described with reference to FIG. 2.

FIG. 2 shows schematically a single multiplexer circuit 18 for splitting a high-frequency multi-component signal 23 into three high-frequency components, one component 24 at a fundamental frequency f₀, one component 25 at the first harmonic frequency 2f₀ and one component 26 at the second harmonic frequency 3f₀. The circuit 18 comprises three signal splitting circuits (for example, in the form of directional filters) 30 arranged in a cascade. The first signal splitting circuit 30a receives at an input (port B) the high-frequency multi-component signal 23. The input signal 23 is split into two components, a first component (as a first output 24 of the multiplexer) at the fundamental frequency f₀ and a second component 27 comprising higher frequency signals, which are output at ports C and D respectively of the first signal splitting circuit 30a. The second component 27 output by the first signal splitting circuit 30a is fed to an input of the second signal splitting signal circuit 30b which divides out a second output 25 of the multiplexer 18 at the first harmonic frequency 2f₀. The remaining components 28 (higher frequency signals) are fed to an input of the third signal splitting signal circuit 30c which divides out a third output 26 of the multiplexer 18 at the second harmonic frequency 3f₀. The remaining components 29 having frequencies at the third and higher harmonics are dissipated to ground via a 50 Ohm impedance, with substantially zero reflection back into the multiplexer 18.

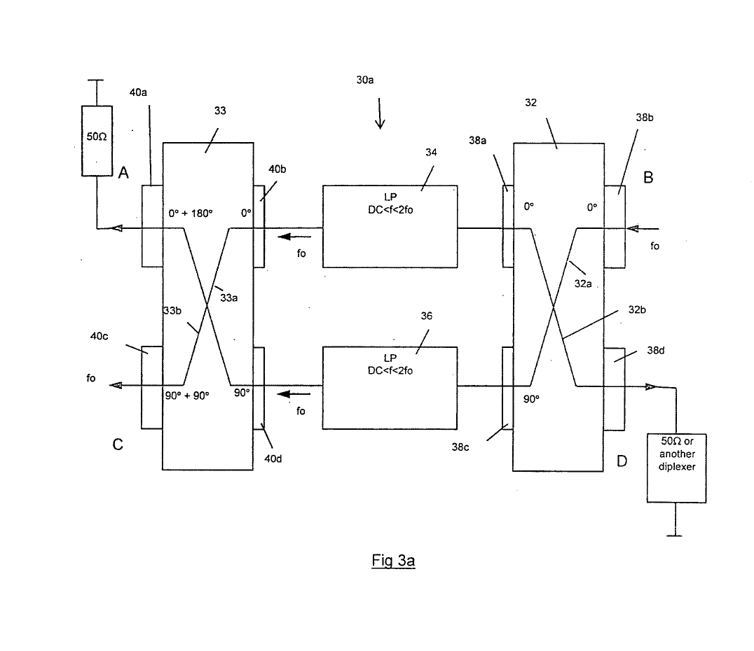

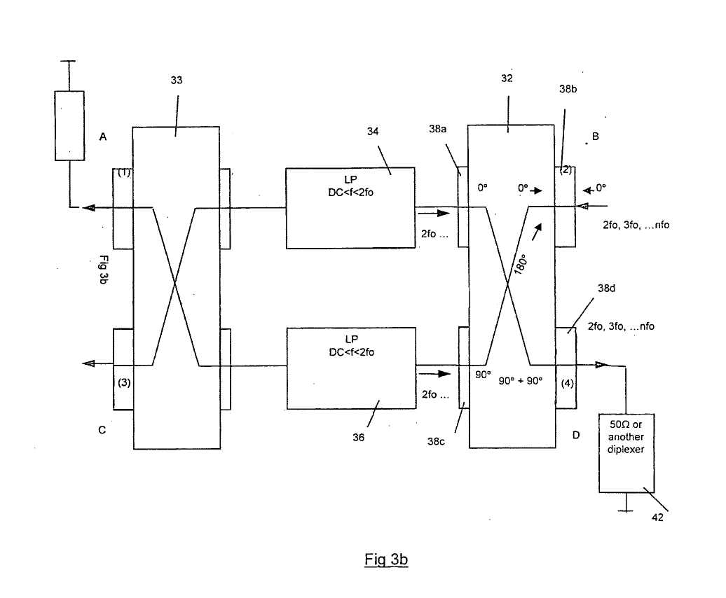

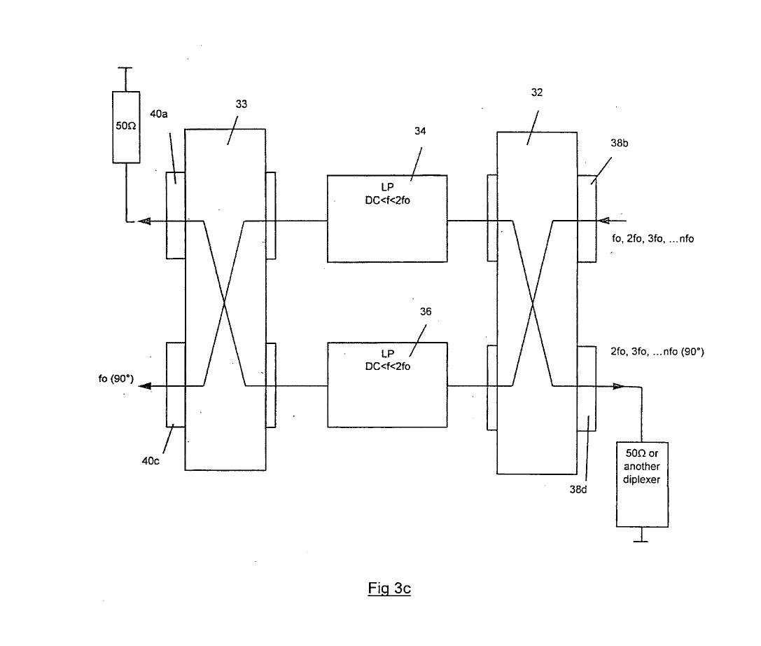

The signal splitting circuits 30 of the multiplexer circuit 18 have excellent properties for ensuring low or negligible levels of reflection by the multiplexer 18 at all frequencies. This is achieved by means of using signal splitting circuits 30 each having a structure as illustrated schematically in FIGS. 3a to 3c, which will now be described in further detail.

FIG. 3a shows the first signal splitting circuit 30a, of the multiplexer circuit 18 illustrated in FIG. 2. The signal splitting circuit 30a comprises a pair of 90° 3db hybrid couplers 32, 33 connected via a pair of signal filters 34, 36 arranged in parallel. The signal splitting circuit 30a may be considered as forming a directional filter. The signal filters 34, 36 have the substantially the same frequency characteristics. In this signal splitting circuit 30a, each signal filter 34, 36 is in the form of a low pass filter, passing frequencies at the fundamental frequencies f₀ or lower, but reflecting higher frequency signals. Each hybrid coupler 32, 33 has four port 40a-d and two transmission lines 32a, 32b, 33a, 33b each connecting two ports of the hybrid coupler 32, 33. Thus, for the first hybrid coupler 32 (in this diagram the coupler on the right side of the diagram) a first transmission line 32a connects the second port 38b to a diagonally opposed third port 38c. A second transmission line 32b connects the first port 38a to the diagonally opposed fourth output port 38d. The transmission lines may be of any convenient type, for example they may be wave guides or micro-strip lines.

The transmission lines 32a, 32b are electrically isolated from each other. The two transmission lines 32a, 32b, of each hybrid circuit 32 are arranged in such a way that a coupling occurs between the lines for signals within the operational bandwidth of the 90° hybrid. The hybrid circuit 32 splits a high-frequency signal at an input into two separate equal amplitude high-frequency output signals, one at each output. A signal diagonally traversing the hybrid circuit experiences a 90° phase shift relative to a signal following a straight-through signal path.

The operation of the signal splitting circuit will now be described, insofar as signals at the fundamental frequency f₀ are concerned, with reference to FIG. 3a. A signal having frequency f₀ applied at port B is fed into a second port 38b of a first coupler 32. This signal is split by the coupler 32 into two components of equal power, which are outputted at the first and third ports 38a, 38c of the first coupler 32, the signal at the third port 38c having a 90° phase difference relative to the first port 38a. Both output signals, at ports 38a, 38c, from the first coupler 32 pass though the low pass filters 34, 36 and are thus inputted at the second and fourth ports 40b, 40d of the second coupler 33. The signal passing from the second port 40b to the first port 40a experiences no relative phase change, whereas the signal passing from the second port 40b to the third port 40c experiences a relative phase change of 90°. On the other hand, the signal (already having experienced a relative phase shift of) 90°, which passes from the fourth port 40d to the first port 40a of the second coupler experiences a further relative phase change of 90°, whereas the signal passing from the fourth port 40d to the third port 40c of the second coupler 33 experiences no further relative phase change. At the first port 40a of the second coupler 33, two Signals of equal power, but 180° out of phase, combine and negatively interfere, effectively cancelling each other out. Any residual current at the first port 40a dissipates to ground. At the third port 40c of the second coupler 33, two signals of equal power, both with +90° relative phase shift combine and positively interfere effectively resulting in a single signal, with little power loss at frequency f₀, but with a phase shift. The net effect of the signal splitting circuit on signals at the fundamental frequency f₀ is therefore simply a phase shift with very little power loss.

The operation of the signal splitting circuit will now be described, insofar as signals at the first harmonic frequency 2f₀ and higher frequencies are concerned, with reference to FIG. 3b. A signal having frequency components higher than f₀ is applied at port B is fed into the second port 38b of the first coupler 32. This signal is split by the coupler 32 into two components of equal power, which are outputted at the first and third ports 38a, 38c of the first coupler 32, the signal at the third port 38c having a 90° phase difference relative to the first port 38a. Both output signals from the first coupler 32 are reflected by the low pass filters 34, 36 and are thus re-inputted at the first and third ports 38a, 38c of the first coupler 32. On reflection at the filters 34, 36 there is a phase shift, but both signals undergo a phase shift of substantially the same amount. The signal passing from the first port 38a back to the second port 38b experiences no relative phase change, whereas the signal passing from the first port 38a back to the fourth port 38d experiences a relative phase change of 90°. On the other hand, the signal (already being 90° out of phase) passing from the third port 38c back to the second port 38b of the first coupler 32 experiences a further relative phase change of 90°, whereas the signal passing from the third port 38c back to the fourth port 38d of the first coupler 32 experiences no further relative phase change. Thus, at the second port 38b of the first coupler 32, two signals of equal power, but 180° out of phase, combine and negatively interfere effectively cancelling each other out. At the fourth port 38d of the first coupler 32, two signals of equal power, both with +90° relative phase shift combine and positively interfere effectively resulting in a single signal, with little power loss at frequency f₀, but with a phase shift. The signal at the fourth port 38d of the first coupler 32 may then be fed to an input of another signal splitter circuit or connected via a 50 Ohm impedance to ground. The net effect of the signal splitting circuit on signals above the fundamental frequency f₀ is therefore simply a phase shift with very little power loss.

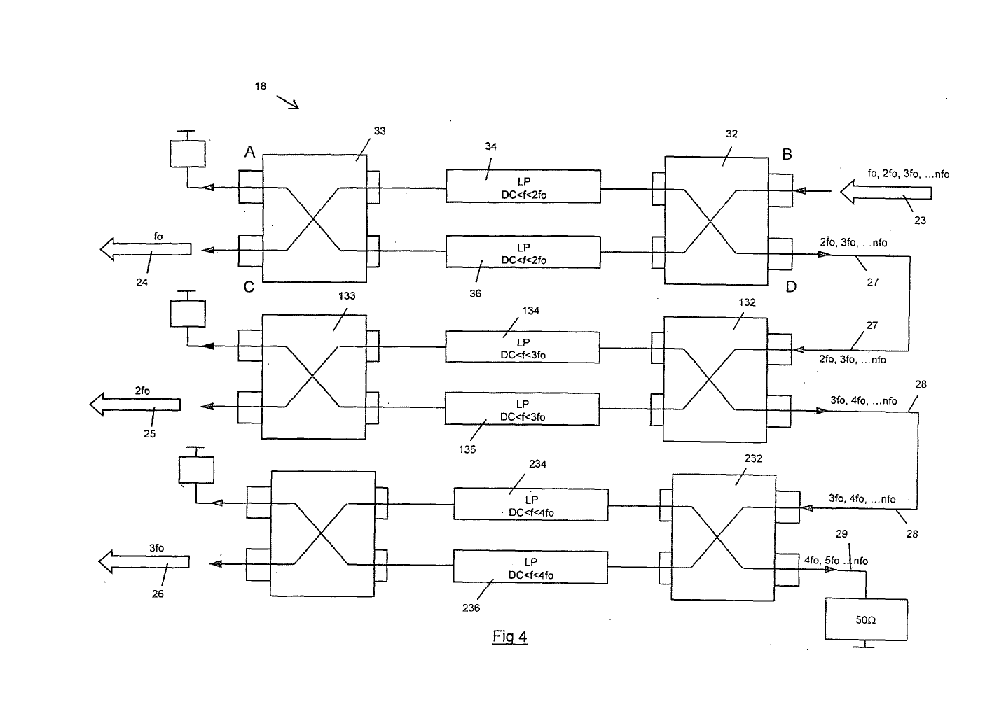

FIG. 3c illustrates the net effect of the operation of the signal splitting circuit for signals comprising components at the fundamental frequency f₀ and components at harmonic higher frequencies. Signals are inputted at the second port 38b and are split into (a) a signal at the fundamental frequency f₀ with a 90° phase shift outputted at the third port 40c and (b) a signal comprising higher frequency components, also with a phase shift, outputted at the fourth port 38d. FIG. 4 shows how three such signal splitting circuits are combined to provide the function of the multiplexer circuit 18 illustrated in FIG. 2. Thus, a high-frequency multi-component signal 23 is received at a second port of a hybrid coupler 32 of a first signal splitting circuit (comprising couplers 32, 33 and low-pass filters 34, 36), the first signal splitting circuit being substantially in the form described above with reference to FIGS. 3a to 3c. A second signal splitting circuit similarly comprises two hybrid couplers 132, 133 connected via two low-pass filters 134, 136. These filters have frequency characteristics that pass components at the first harmonic frequency 2f₀ or lower but reflect higher frequency components. The input signal 23 is split into two components by the first signal splitting circuit, yielding the first output 24 at the fundamental frequency f₀ and a second output 27 comprising higher frequency signals, which are fed to the second port of the first hybrid couplers 132 of the second signal splitting circuit. As a result of the frequency characteristics of the low pass filters 134, 136 of the second signal splitting circuit, the incoming signal 27 is split into the output 25 at the first harmonic frequency 2f₀ and the higher frequency signals 28. These higher frequency signals 28 are fed to the third signal splitting signal circuit, which has low pass filters 234, 236 which pass components at the second harmonic frequency 3f₀ or lower but reflect higher frequency components. Thus, the incoming signal is split into the third output 26 at the second harmonic frequency 3f₀ and the remaining higher frequency components 29 are dissipated, to ground.

The multiplexer circuit shown in FIG. 4 is illustrated as a signal splitting multiplexer (or demultiplexer). It will be appreciated that the same structure of circuit may be used in reverse configuration to cause multiple signals at different frequencies to be combined. Simply, the three outputs 24, 25, and 26 can be used as inputs such that a composite signal is outputted at the second port (labelled B) of the first signal splitting circuit.

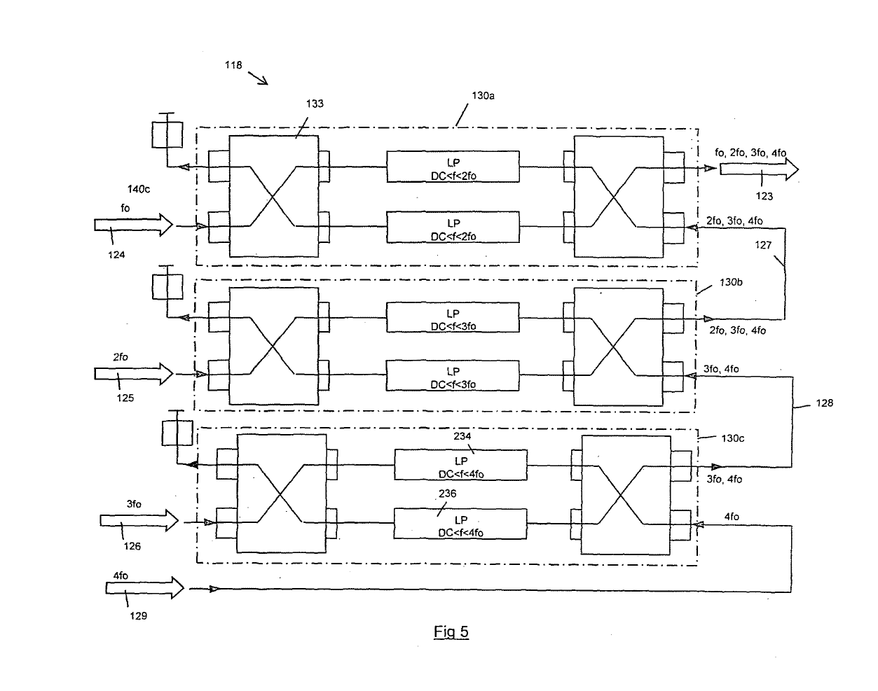

FIG. 5 shows a multiplexer circuit 118 according to a second embodiment of the invention. It will be seen that the structure of the circuit 118 is very similar to that shown in FIG. 4. However, in this case, the multiplexer is used in a high frequency non-linear measurement system to combine four RF signals into a single combined signal, and as such the signal splitting circuits operate in reverse to combine signals. Thus, there are three signal splitting circuits 130a, 130b, 130c arranged in a cascade. To avoid confusion the circuits 130a, 130b, 130c in FIG. 5 will now be referred to as “signal combining circuits”. The principles of operation of each signal combining circuit is substantially identical to the principles of operation of the signal splitting circuit shown in FIGS. 3a to 3c, except that the signal combining circuit is used in reverse. Thus, at the fourth port of the third signal combining circuit 130c an input signal 129 at the third harmonic frequency 4f₀ is received. An input signal 126 at the second harmonic frequency 3f₀ is received at the third port of the third signal combining circuit 130c. The third signal combining circuit 130c has low pass filters 234, 236 which pass components at the second harmonic frequency 3f₀ or lower but reflect higher frequency components. As a result, the input signals 126, 129 are combined and outputted at the second port of the circuit 130c as a composite signal 128, which is received at the fourth port of the second signal combining circuit 130b. The second signal combining circuit 130b also receives at its third port an input signal 125 at the first harmonic frequency 2f₀. The second signal combining circuit 130b has low pass filters 134, 136 which pass components at the first harmonic frequency 2f₀ or lower but reflect higher frequency components. Thus, in a similar manner to that of the third signal combining circuit, the input signal 125 at the first harmonic frequency 2f₀ and the composite signal 128 (higher harmonics) are combined and outputted at the second port of the circuit 130b as a composite signal 127. This composite signal 127 is combined with a signal 124 at the fundamental frequency f₀ to produce a composite output signal 123 at the second port of the circuit having components at the fundamental frequency f₀ and at the first, second and third harmonic frequencies. It will be appreciated that the various input signals all undergo phase shifts as they pass through the signal splitting circuits 130a, 130b, and 130c. The multiplexer circuit 118 combines the RF signals 124, 125, 126, 129 into a composite signal 123 with very little power loss and with very little reflection.

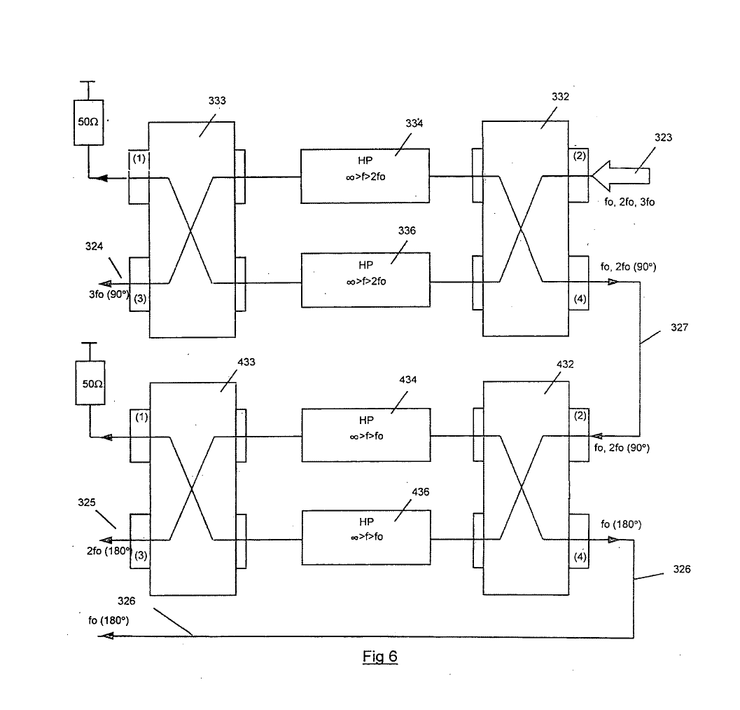

It will be appreciated that multiplexer circuits for combining or splitting RF signals with very little power loss and with very little reflection can be made from a variety of different arrangements and configurations of hybrid couplers and RF filters. For example, high pass, or band-pass filters could be utilized. FIG. 6 shows as an example a multiplexer circuit (arranged for demultiplexing a composite signal) according to a third embodiment of the invention, which utilizes high-pass filters. The principle of operation is very similar to that of the other illustrated multiplexer circuits. Thus, FIG. 4 shows how three such signal splitting circuits are combined to provide the function of the multiplexer circuit 18 illustrated in FIG. 2. Thus, a high-frequency multi-component signal 323 is received at a second port of a hybrid coupler 332 of a first signal splitting circuit (comprising couplers 332, 333 and high-pass filters 334, 336). The high-pass filters 334, 336 allow passage of signals with frequencies at the second harmonic frequency 3fo or higher, and reflects signals with lower frequencies. A second signal splitting circuit similarly comprises two hybrid couplers 432, 433 connected via two high-pass filters 434, 436, which allow passage of signals with frequencies of at the first harmonic frequency 2fo or higher, and reflects signals with lower frequencies. The input signal 323 is therefore split into two components by the first signal splitting circuit, yielding a, first output 324 at the second harmonic frequency 3f₀ and a second output 327 comprising lower frequency signals, which are fed to the second port of the first hybrid coupler 432 of the second signal splitting circuit. As a result of the frequency characteristics of the high pass filters 434, 436 of the second signal splitting circuit, the incoming signal 327 is split into the output 325 at the first harmonic frequency 2f₀ and the output 326 at the fundamental frequency f₀.

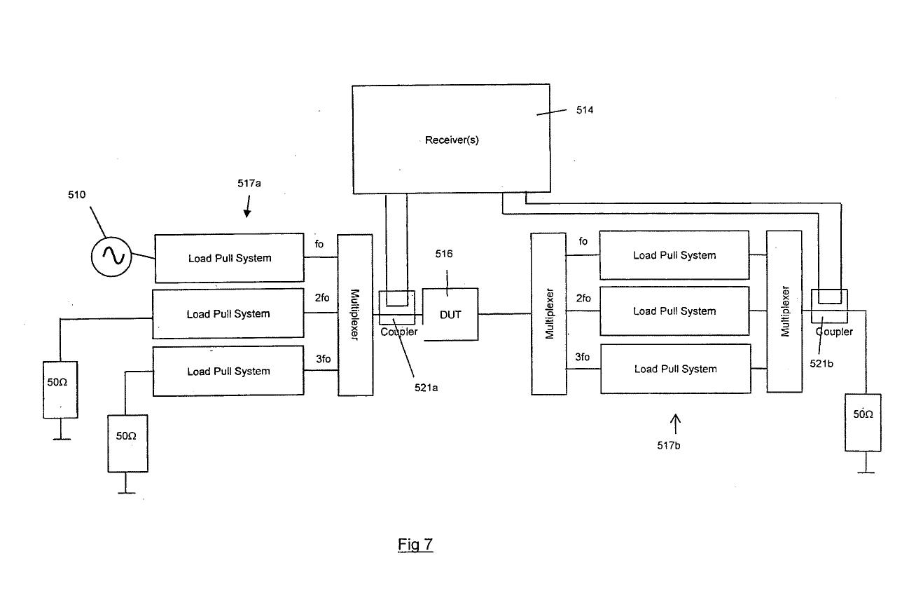

FIG. 7 shows a non-linear measurement system with active load pull circuits and multiplexers according to a fourth embodiment of the present invention. The measurement system has a basic structure similar to that of the measurement system of FIG. 1, but shows a signal measuring device (oscilloscope) 514 connected via one coupler 521a to an input port of the DUT 516 and connected via another coupler 521b to an output of the multiplexer circuit 517b on the output side of the DUT 516. It also shows a separate wave form source 510 on the input side for use by the load pull circuits 517a on the input side of the measurement system.

The illustrated measurement system facilitates the improvement of the design of amplifier circuits including a transistor (for example an LDMOS device), by means of analysing the behaviour of the transistor. A comprehensive fundamental frequency load-pull investigation can be performed on a biased (with DC source) LDMOS transistor as the DUT. This information can then be used to improve the performance and efficiency of a (non-linear) device, in a manner known in the art. For example, harmonic tuning can be performed on the device by applying a load at the fundamental frequency while changing the second and third harmonic loads.

Whilst the present invention has been described and illustrated with reference to particular embodiments, it will be appreciated by those of ordinary skill in the art that the invention lends itself to many different variations not specifically illustrated herein. By way of example only, certain possible variations will now be described.

The signal splitting circuits could use band-pass filters such that an incoming signal including frequency components lower than, within, and higher than the frequency band of the filter is split into a first signal with components only within the frequency band and a second signal with remaining components having both frequencies higher than the frequency band and frequencies lower than the frequency band.

The filters of each pair of filters in each signal splitting circuit could have different frequency characteristics. For example, the phase shift imparted by one filter may be different from another. To ensure low reflection of signals at the multiplexer it may then be necessary to add a phase shifting device, such as an extra length of transmission line, so that signals reflected back through the hybrid couplers are close to or exactly 180 degrees out of phase so as to negatively interfere sufficiently well. It may be possible to construct a multiplexer circuit having a pair of filters in each signal splitting circuit having different frequency characteristics such that one filter passes signals of a frequency that are blocked by the other filter of the pair. Such a construction may result in poorer performance in the multiplexer, such as greater power loss or greater reflections by the multiplexer at certain frequencies.

The multiplexer circuit illustrated in the Figures has an expandable architecture. Further signal splitting circuits, having a succession of different frequency characteristics (for example successively higher low-pass filters), can be added in the cascade of signal splitting circuits to produce multiplexers able to split a signal into as many different frequency components as are desired. Signal amplifiers may be added if there is appreciable power loss as a result of a large number of signal splitting circuits being arranged in series, to ensure that higher frequency signals are not significantly attenuated.

Rather than using two hybrid couplers and two parallel filters as the building block for the cascade of directional filters that form the multiplexer/demultiplexer circuit, a different structure of directional filter could be used. For example, two parallel arranged rectangular waveguides operating in the dominant TE₁₀ mode connected by a series of one or more cylindrical direct-coupled cavity resonators operating in the circularly polarised TE₁₁ mode (for example, the cylindrical cavity resonators connecting from midway along one rectangular waveguide to midway along the other parallel-arranged rectangular waveguide) could be used. Alternatively, it might also be feasible to use directional filters having a strip-line structure.

Where in the foregoing description, integers or elements are mentioned which have known, obvious or foreseeable equivalents, then such equivalents are herein incorporated as if individually set forth. Reference should be made to the claims for determining the true scope of the present invention, which should be construed so as to encompass any such equivalents. It will also be appreciated by the reader that integers or features of the invention that are described as preferable, advantageous, convenient or the like are optional and do not limit the scope of the independent claims. Moreover, it is to be understood that such optional integers or features, whilst of possible benefit in some embodiments of the invention, may not be desirable, and may therefore be absent, in other embodiments.

1. A high frequency non-linear measurement system including one or more multiplexer circuits, wherein each multiplexer circuit comprises a first signal-combining circuit and a second signal-combining circuit, each signal-combining circuit comprising a pair of directional couplers connected via a pair of signal filters arranged in parallel.

2. A high frequency non-linear measurement system including one or more demultiplexer circuits, wherein each demultiplexer circuit comprises a first signal-splitting circuit and a second signal-splitting circuit, each signal-splitting circuit comprising a pair of directional couplers connected via a pair of signal filters arranged in parallel.

3. A measurement system according to claim 1, wherein the signal filters of each pair of signal filters have substantially the same frequency characteristics.

4. A measurement system according to claim 1, wherein the signal filters of the first signal-combining circuit have different frequency characteristics from the signal filters of the second signal-combining circuits.

5. A measurement system according to claim 1, wherein the directional couplers are in the form of 3 dB 90 degree hybrid couplers.

6. A measurement system according to claim 1, wherein the a plurality of signal-combining circuits are arranged in a cascade, an output of the signal-combining circuit in the cascade providing an input to a subsequent signal-combining circuit in the cascade.

7. A measurement system according to claim 1, wherein the one or more multiplexer circuits form part of a load pull system for emulating an impedance at one of the ports of a device-under-test to be analysed by the measurement system.

8. A measurement system according to claim 1, wherein the measurement system includes a waveform generator that in use generates a waveform received by at least one of the one or more multiplexer circuits.

9. A measurement system according to claim 8, wherein the waveform generator is arranged to generate both a giga-Hertz frequency waveform at the same time as a mega-Hertz frequency waveform.

10. A measurement system according to claim 1, wherein the measurement system is arranged to apply a signal at a device under test that comprises a DC component, a low-frequency modulation signal component and a high-frequency signal component.

11. A measurement system according to claim 1, wherein the measurement system is arranged to measure signals having a low-frequency modulation signal component and signals having a high-frequency signal component, and to extract information contained in signals at such frequencies.

12. A method of measuring the response of an electronic device to a high frequency input signal, the method including the steps of:
providing an electronic device under test, the device having at least two ports,
providing a plurality of high-frequency signals at different frequencies,
modifying the plurality of high-frequency signals,
multiplexing the modified plurality of high-frequency signals into a combined load-pull signal,
applying a high-frequency test signal comprising the load-pull signal at a port of the device under test, and
measuring the response of the device-under-test to the test signal applied to the device,
wherein the multiplexing step is conducted by passing signals via a multiplexer circuit comprising a first signal-combining circuit and a second signal-combining circuit, each signal-combining circuit comprising a pair of directional couplers connected via a pair of signal filters arranged in parallel.

13. A method of measuring the response of an electronic device to a high frequency input signal, the method including the steps of:
providing an electronic device under test, the device having at least two ports,
applying a high-frequency test signal, comprising a plurality of different high-frequency load-pull components, at a port of the device under test,
measuring the response of the device-under-test to the test signal applied to the device,
and
demultiplexing a high-frequency composite signal into a plurality of component parts,
wherein the demultiplexing step is conducted by passing signals via a multiplexer circuit comprising a first signal-splitting circuit and a second signal-splitting circuit, each signal-splitting circuit comprising a pair of directional couplers connected via a pair of signal filters arranged in parallel.

14. A method according to claim 12, wherein the method includes using a measurement system according to claim 1.

15. A method of improving the design of a high frequency high power device or a circuit including a high frequency high power device, the method including the steps of analysing the behaviour of the device either by using the measurement system of or by performing the method of claim 12, and then modifying the design of the device or modifying the circuit including the device in consideration of the results of the analysing of the behaviour of the device.

16. A method of manufacturing a high frequency high power device or a circuit including a high frequency high power device, the method including the steps of improving the design of a similar existing device or of an existing circuit including such a device by performing the method of claim 15 and then manufacturing the device or the circuit including the device in accordance with the improved design.

17. A high frequency non-linear measurement system including one or more multiplexer/demultiplexer circuits, wherein each multiplexer/demultiplexer circuit comprises a cascade of high frequency directional filters.

18. A measurement system according to claim 2, wherein the signal filters of each pair of signal filters have substantially the same frequency characteristics.

19. A measurement system according to claim 2, wherein the signal filters of the first signal-splitting circuit have different frequency characteristics from the signal filters of the second signal-splitting circuits.

20. A measurement system according to claim 2, wherein the directional couplers are in the form of 3 dB 90 degree hybrid couplers.

21. A measurement system according to claim 2, wherein the a plurality of signal-splitting circuits are arranged in a cascade, an output of the signal-combining circuit in the cascade providing an input to a subsequent signal-splitting circuit in the cascade.

22. A measurement system according to claim 2, wherein the one or more demultiplexer circuits form part of a load pull system for emulating an impedance at one of the ports of a device-under-test to be analysed by the measurement system.

23. A measurement system according to claim 2, wherein the measurement system includes a waveform generator that in use generates a waveform received by at least one of the one or more demultiplexer circuits.

24. A measurement system according to claim 23, wherein the waveform generator is arranged to generate both a giga-Hertz frequency waveform at the same time as a mega-Hertz frequency waveform.

25. A measurement system according to claim 2, wherein the measurement system is arranged to apply a signal at a device under test that comprises a DC component, a low-frequency modulation signal component and a high-frequency signal component.

26. A measurement system according to claim 2, wherein the measurement system is arranged to measure signals having a low-frequency modulation signal component and signals having a high-frequency signal component, and to extract information contained in signals at such frequencies.

27. A method according to claim 13, wherein the method includes using a measurement system according to claim 1.
